(19) United States
(12) Patent Application Publication
(10) Pub. No.: US 2003/0042593 A1
(43) Pub. Date: Mar. 6, 2003

(54) Pad grid array leadless package and method of use

(75) Inventor: David M. Gilbert, (US)

Correspondence Address: ON Semiconductor, Patent Administration Dept - MD A230, P.O. Box 62890, Phoenix, AZ, 85082-2890, US

(73) Assignee: Semiconductor Components Industries, LLC

(21) Appl. No.: 09/940,448

(22) Filed: Aug. 29, 2001

(51) Int. Cl. H01L 23/48

(52) U.S. Cl. 257/690

(57) ABSTRACT

A pad grid array semiconductor package (28) provides interconnect pads (30) of equal pad area and matrixed locations, placing an interconnect pad in a fixed location relative to an adjacent interconnect pad. Die pad (48) and interconnect pads (30) are formed from an etched, or otherwise formed, conductive lead frame. Die pad (48) is in full contact with semiconductor die (50), providing pad grid array interconnect pads (30) in electrically conductive contact to semiconductor die (50). Interconnect pad (58) is removed in an alternate configuration to provide spacial orientation of pad grid array package (56).

### BACKGROUND OF THE INVENTION

The present invention relates in general to leadless packages and, more particularly, to leadless, pad grid array packages having equally dimensioned pads.

In general, contemporary electronic devices are designed with critical design specifications such as size, weight and power consumption in mind. The size, weight and power consumption of the electronic devices are continuously being diminished as the designs mature. One method to reduce the size of the electronic devices is to reduce the size of the individual components that are used to implement the electronic device. Leadless packages, for example, are used to reduce the amount of printed circuit board area required by the electronic component.

Quad Flatpack No-lead (QFN) packages provide a leadless package having interconnect pads positioned along all four sides of the bottom surface of the package. The interconnect pads are typically connected to the semiconductor die, contained within the QFN package, using wire bonding techniques. Additionally, the QFN package provides a conductive area on the bottom of the package, adjacent to the interconnect pads, which is larger than the interconnect pads. FIG. 1 provides a typical representation of prior art QFN package 10. Dimension 16 illustrates the outer dimension of package 10, which defines the entire area of package 10. Interconnect pads 12 are positioned on the bottom side of QFN package 10 along all four sides, surrounding die pad 14. Die pad 14 and interconnect pads 12 have a bottom and a top surface. The bottom surface of die pad 14 and interconnect pads 12 are visible from the bottom side of QFN package 10. The top surface of die pad 14 and interconnect pads 12 are internal to QFN package 10. A semiconductor die (not shown) is directly mounted to the top surface of die pad 14 where interconnect pads 12 provide connection to the semiconductor die, via wire bonds extending from the top surface of interconnect pads 12 and the top surface of the semiconductor die. The bottom surface of the semiconductor die is in direct contact with the top surface of die pad 14, since the semiconductor die is directly mounted to die pad 14.

The dissimilarity between the size of die pad 14 and interconnect pads 12 of the prior art QFN packages provide several detrimental effects. QFN package 10 is typically attached to a printed circuit board, where conductive signal traces on the printed circuit board mate to interconnect pads 12 and a conductive, heat transfer pad mates to die pad 14. During board level assembly, a large amount of solder paste, or other conductive board adhesive, is applied to die pad 14 and a relatively smaller portion of solder paste is applied to interconnect pads 12. The proximity of the varying amounts of solder paste creates board level assembly problems such as electrical shorting, misalignment and solder thickness control.

FIG. 2 illustrates a similar prior art semiconductor package 18 having die pad 20 and interconnect pads 22. The proximity of varying amounts of solder paste during board application of semiconductor package 18 creates a tilting effect, since the solder paste applied to die pad 20 creates a greater resistance force than solder paste applied to interconnect pads 22. The increased mechanical resistance due to the volume of solder paste present on die pad 20, causes side 24 of semiconductor package 18 to be at a higher elevation with respect to the board than side 26 of semiconductor package 18 after board placement is complete. In addition, the wetted surface tension forces due to solder reflow on die pad 20 are greater than the wetted surface tension forces due to solder reflow on interconnect pads 22. The difference in tension forces due to solder reflow creates a potential misalignment condition of semiconductor package 18 relative to the printed circuit board.

Hence, there is a need for an improved semiconductor package which substantially eliminates solder reflow shorting due to variation in pad size, provides consistent board mounting design rules regardless of package configuration and provides for self-centering of package alignment due to balanced, wetted surface tension forces.

### BRIEF DESCRIPTION OF THE DRAWINGS

FIG. 1 is an illustration of a prior art QFN package;

FIG. 2 is an illustration of a prior art leadless package;

FIG. 3 is an illustration of the interconnect pad surface of a pad grid array leadless package;

FIG. 4 is an illustration of an alternate configuration of a pad grid array leadless package;

FIG. 5 is a side view of a printed circiut board assembly using the pad grid array leadless package of FIG. 3;

FIG. 6 is an illustration of an alternate configuration of a pad grid array leadless package; and

FIG. 7 is an illustration of an alternate configuration of a pad grid array leadless package.

### DETAILED DESCRIPTION OF THE DRAWINGS

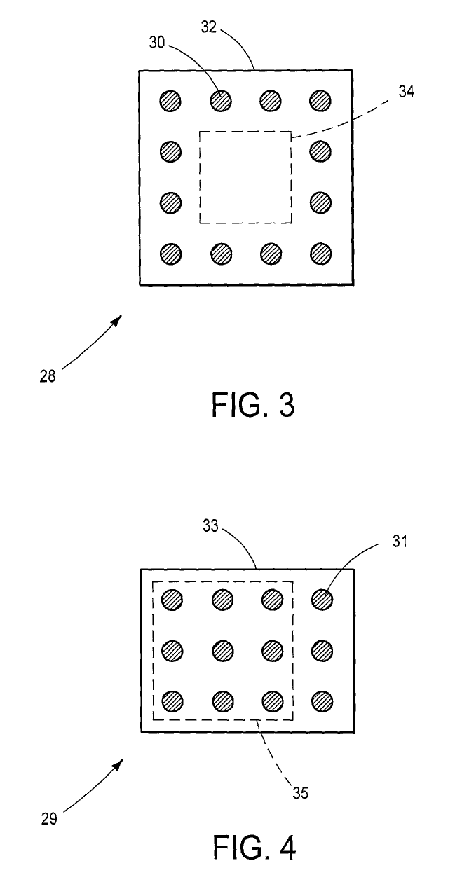

In FIG. 3, a bottom view of an improved semiconductor package 28 is illustrated. Semiconductor package 28 is illustrated having outer dimension 32, which defines the total package area of semiconductor package 28. Circular interconnect pads 30 are arranged as equally spaced columns and equally spaced rows, where the number of rows equals the number of columns. Although FIG. 3 illustrates an equal number of interconnect pad rows and interconnect pad columns, other configurations of interconnect pad matrices result, which define a different number of interconnect pad rows with interconnect pad columns as necessary. Dimension 34 illustrates a possible placement of the semiconductor die pad in relation to the center most interconnect pads 30. Interconnect pads 30 arranged along each of four sides of semiconductor package 28 provide electrical connection to semiconductor die (not shown), which is mounted to die pad 34. The electrical connections are typically implemented using wire bond techniques from the top sides of interconnect pads 30 to the top side of the semiconductor die (not shown).

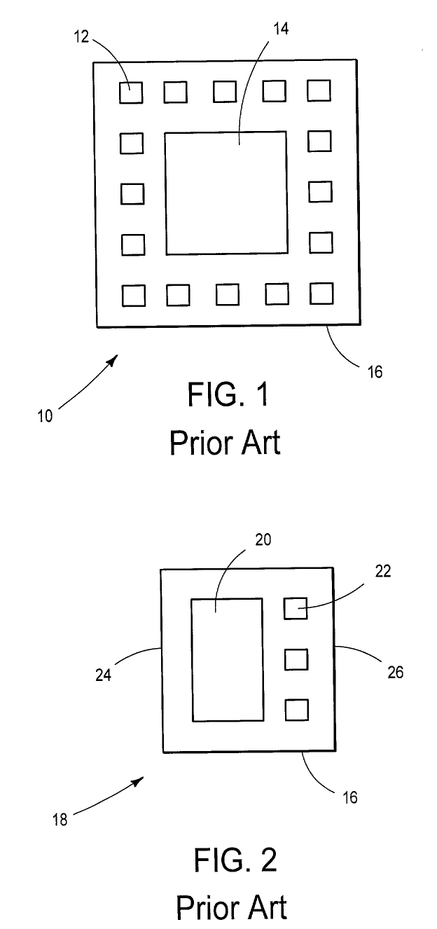

As can be seen from FIG. 3, interconnect pads 30 are arranged in rows and columns, such that the separation of one interconnect pad to an adjacent interconnect pad is essentially uniform. In addition, the total area of each interconnect pad is held essentially uniform. Although the geometries of interconnect pads 30 are shown to be circular, other configurations of interconnect pad geometries having equal surface areas are also possible. Interconnect geometries including square, rectangular, hexagonal, octagonal etc. may be used in place of the circular geometries shown for interconnect pads 30, while maintaining the relative surface area of each interconnect pad constant. The separation distance and substantially constant surface area of interconnect pads 30 are distinct advantages of semiconductor package 28, relative to prior art semiconductor packages of FIGS. 1 and 2, for several reasons discussed below.

FIG. 4 illustrates an additional configuration of a typical pad grid array package having an equally dimensioned pad grid array. Dimension 33 defines the outline of semiconductor package 29 having interconnect pads 31 uniformly spaced in both the horizontal and vertical directions. The number of rows of interconnect pads does not equal the number of columns of interconnect pads, where die pad 35 is illustrated to be situated over the 3, left-most columns of interconnect pads 31. The fourth column of interconnect pads are used to provide a conductive interface get to the semiconductor die (not shown) attached to die pad 35. Semiconductor package 29, for example, is beneficial for use with a 3-lead device such as an NPN transistor or a power Metal Oxide Semiconductor Field Effect Transistor (MOSFET).

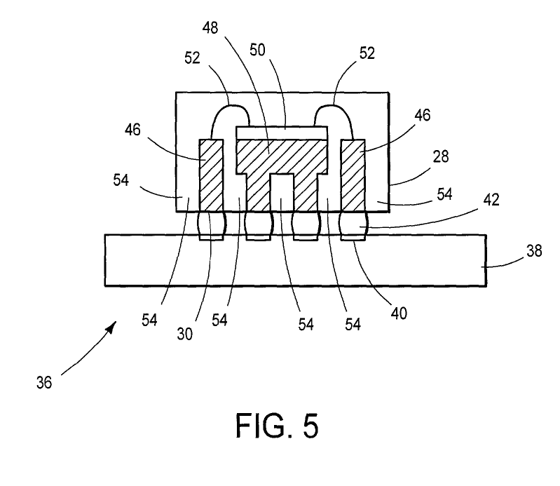

FIG. 5 illustrates a side view of a typical printed circuit board assembly 36. Printed circuit board 38 provides conductive traces 40 which allow electrical connection points between printed circuit board 38 and semiconductor package 28. Semiconductor package 28 represents a side view of the semiconductor package of FIG. 3. Conductive portions 46 and 48 represent the remaining portions of a conductive leadframe after an etching, stamping, machining or other forming process is performed, removing conductive material from regions 54. Semiconductor die 50 is attached to conductive die pad region 48 of the formed leadframe and conductive portions 46 are connected to the top surface of semiconductor die 50 using wire bonds 52. The opposite ends of conductive portions 46 represent interconnect pads 30. Regions 54 are subsequently filled with an encapsulant, to complete the formation of semiconductor package 28.

The electrical connections between semiconductor package 28 and printed circuit board 38 are implemented using solder paste, or another conductive adhesive, 42 between interconnect pads 30 and conductive traces 40. During board level assembly of semiconductor package 28, solder paste 42 is applied to interconnect pads 30 and semiconductor package 28 is subsequently pressed onto printed circuit board 38. The application pressure exerted on semiconductor package 28 causes solder paste 42 to slightly bulge in a lateral direction relative to the exertion force as shown in FIG. 5. Due to the equal surface areas of interconnect pads 30, equal amounts of solder paste 42 are displaced in the lateral direction for each interconnect pad 30, such that no interconnect pad is shorted to any other interconnect pad due to extruding solder paste. During the solder reflow process, printed circuit board assembly 36 is subjected to elevated temperatures in order to reflow solder paste 42 over interconnect pads 30 and conductive traces 40 to complete the electrical connection between printed circuit board 38 and semiconductor package 28. During solder reflow, wetting forces on interconnect pads 30 are exerted, causing the solder to form spherically shaped balls, centered within interconnect pads 30 and conductive traces 40. In addition, the wetting forces caused by solder reflow tend to bring semiconductor package 28 into alignment with conductive traces 40 on printed circuit board 38, since the wetting forces exerted by each interconnect pad 30 are substantially equal.

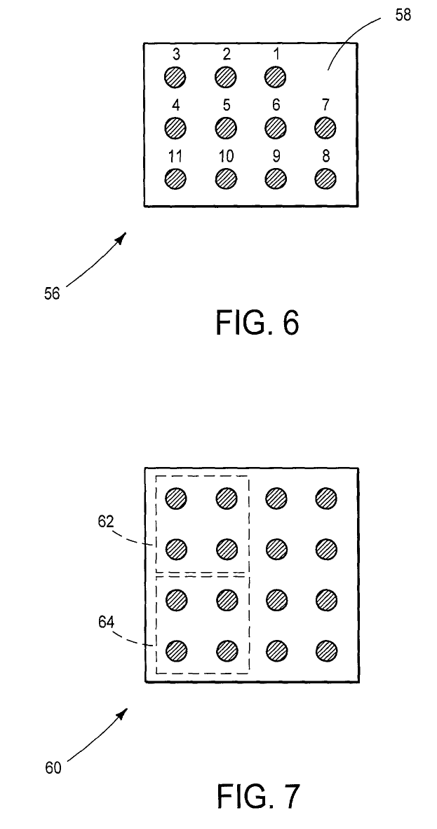

FIG. 6 illustrates an alternate pad grid array package 56, whereby one pad 58 is missing from one corner of the pad grid array pattern. It would be advantageous to implement such a pad grid array pattern, so that a spacial orientation of the pad grid array package is readily ascertained. Pad numbering order is readily established, for example, if pad numbering rules establish that the upper right hand corner of the pad grid array is to contain the missing pad. Once the missing pad has been oriented to the upper right hand corner, for example, pad count increments starting at #1 commences in spiral fashion, starting with the pad immediately to the left of the missing pad location. Other orientation rules are available, which could otherwise properly orient the pad grid array.

FIG. 7 illustrates pad grid array package 60, whereby multiple die pads 62 and 64 exist within package 60 and interconnect pads to the right of die pads 62 and 64 are used for electrical interconnect to semiconductor die (not shown) attached to die pads 62 and 64. Other configurations having more than two die pads are achievable for complex integrated circuits requiring more than two semiconductor die.

A first advantage of the essentially uniform separation distance of interconnect pads 30, allows a reduced complexity for solder paste application during the board mount phase of semiconductor package 28. The distance between the geometric center of one interconnect pad to the geometric center of an adjacent interconnect pad, in either the horizontal or vertical direction, is essentially uniform. Essentially uniform separation distances allow for a simplified algorithm for automated solder paste applicators, since the geometric center of a single interconnect pad is required to be calculated only one time. The location of adjacent interconnect pads is an essentially uniform distance, which is readily preset in automated solder paste application machinery. In addition, the foot print layout of conductive traces 40 for semiconductor device 28 on printed circuit board 38 is not complicated, since the foot print layout is a single matrix, or essentially uniform arrangement, having any variation of interconnect pad rows with interconnect pad columns.

A second advantage of the semiconductor package of FIG. 3 results in a balanced placement force of semiconductor package 28 during board placement of semiconductor package 28 after application of solder paste 42 to interconnect pads 30. Equal amounts of solder paste, or any other conductive adhesives, are dispensed onto interconnect pads 30. Since the volume of solder paste existing on each interconnect pad 30 is substantially equal, each interconnect pad 30, with an associated application of solder paste, presents a substantially equal placement force against printed circuit board 38. The balanced placement force substantially eliminates tilting of the semiconductor package during the placement phase, such that all points on the top side of semiconductor package 28 are at a relatively constant height with respect to board 38. The balanced placement force advantage is also realized using the package of FIG. 4.

A third advantage of semiconductor packages 28 and 29 results in a balanced solder reflow of solder paste 42 onto interconnect pads 30. Interconnect pads 30, are circular, which provide an optimum geometry to effect maximum solder reflow coverage onto interconnect pads 30. Geometric shapes other than circular, which have discontinuities along the outer edges, such as square and octagonal, do not produce optimum solder coverage, since solder resists reflow to the discontinuities.

A fourth advantage semiconductor packages 28 and 29 provides substantially balanced wetting forces for each interconnect pad. Since each interconnect pad 30 exerts relatively constant and equal wetting tension forces during solder reflow, semiconductor package 28 tends to center itself with respect to conductive traces 40. Self-centering of semiconductor device 28 onto printed circuit board 38 substantially eliminates unintentional shorting of conductive traces 40 by skewed interconnect pads 30 due to unequal wetting tension forces.

A fifth advantage of the semiconductor packages of FIGS. 3 & 4 is provided by the substantially equal surface areas of interconnect pads 30, providing for a balanced volume of solder paste 40 to be dispensed onto interconnect pads 30. An equal volume of solder paste dispensed onto interconnect pads 30 controls the amount of lateral solder paste protrusion during the placement of semiconductor package 28 onto board 38. Once the lateral solder paste protrusion is controlled, interconnect pad to adjacent interconnect pad shorts are substantially eliminated.

In summary, a pad grid array package is provided having essentially uniformly dimensioned pad grid arrays. The essentially uniform area of interconnect pads allows balanced placement force, balanced solder reflow, self-centering during solder reflow and reduced pad to pad short circuits due to lateral solder paste protrusion. The essentially uniform relative location of interconnect pads to adjacent interconnect pads provides a simplified solder paste dispensing function and facilitates simplified layouts of printed circuit board traces due to the uniformity of the interconnect pad matrix. Alternate interconnect pad arrangements yield package orientation advantages.

What is claimed is:

1. A semiconductor package, comprising:
a conductive leadframe having first and second surfaces;
a die pad formed using the first surface of the conductive leadframe; and
a first portion of interconnect pads having equal surface area formed using the second surface of the conductive leadframe, wherein a second portion of the interconnect pads are continuous with the die pad.

2. The semiconductor package of claim 1, wherein the die pad comprises:
a first conductive surface coplanar with the first surface of the conductive leadframe; and
a second conductive surface coplanar with the second surface of the conductive leadframe.

3. The semiconductor package of claim 2, wherein the second portion of interconnect pads are formed from the second conductive surface of the die pad.

4. The semiconductor package of claim 1, wherein the first portion of interconnect pads comprises:
a first conductive surface coplanar with the first surface of the conductive leadframe; and
a second conductive surface coplanar with the second surface of the conductive leadframe.

5. The semiconductor package of claim 4, wherein the first portion of interconnect pads are isolated from the second portion of interconnect pads.

6. A pad grid array package, comprising:
a first set of interconnect pads having substantially equivalent surface geometry formed from a conductive leadframe as a matrix on a first surface of the pad grid array package; and
a die pad formed from the conductive leadframe continuous with the first set of interconnect pads.

7. The semiconductor package of claim 6, wherein the die pad comprises:
a first conductive surface coplanar with the first surface of the conductive leadframe; and
a second conductive surface coplanar with the second surface of the conductive leadframe.

8. The semiconductor package of claim 7, wherein the first set of interconnect pads are formed from the second conductive surface of the die pad.

9. The semiconductor package of claim 6 further comprising a second set of interconnect pads having substantially equivalent surface geometry formed from the conductive leadframe on the first surface of the pad grid array package.

10. The semiconductor package of claim 9, wherein the surface geometry of the first set of interconnect pads is substantially equivalent to the surface geometry of the second set of interconnect pads.

11. The semiconductor package of claim 9, wherein the second set of interconnect pads are isolated from the first set of interconnect pads.

12. An integrated circuit, comprising:
a leadframe having first and second surfaces;
at least one die pad formed from the leadframe; and
a first set of interconnect pads formed from the leadframe continuous with the at least one die pad, wherein the first set of interconnect pads have substantially equivalent surface area.

13. The integrated circuit of claim 12, wherein the at least one die pad comprises:
a first surface coplanar with the first surface of the leadframe; and
a second surface coplanar with the second surface of the leadframe.

14. The integrated circuit of claim 13, wherein the first set of interconnect pads are formed from the second surface of the die pad.

15. The integrated circuit of claim 12 further comprising a second set of interconnect pads having substantially equivalent surface geometry formed from the leadframe.

16. The integrated circuit of claim 15, wherein the surface geometry of the first set of interconnect pads is substantially equivalent to the surface geometry of the second set of interconnect pads.

17. The integrated circuit of claim 15, wherein the second set of interconnect pads are isolated from the first set of interconnect pads.

18. A method of using a pad grid array package to form a printed circuit board assembly, comprising:
applying equal amounts of a conductive adhesive to interconnect pads of the pad grid array package;
pressing the pad grid array package onto a printed circuit board;
maintaining a substantially constant separation distance between the pad grid array package and the circuit board; and
reducing lateral protrusion of the conductive adhesive.

19. The method of claim 18 wherein maintaining a constant separation distance comprises providing equal placement force from the interconnect pads to the printed circuit board.

20. The method of claim 19 wherein reducing lateral protrusion includes using the equal amounts of the conductive adhesive to provide a substantially uniform lateral protrusion.
